(19) United States
(12) Patent Application Publication
(10) Pub. No.: US 2026/0006894 A1
(43) Pub. Date: Jan. 1, 2026

(54) MINORITY CARRIER COLLECTOR FOR DIODE AND TRANSISTOR

(71) Applicant: Texas Instruments Incorporated, Dallas, TX (US)

(72) Inventors: Zachary Lee, Fremont, CA (US); Alexei Sadovnikov, Sunnyvale, CA (US)

(21) Appl. No.: 18/759,864

(22) Filed: Jun. 29, 2024

(51) Int. Cl. H01L 29/78; H01L 21/265; H01L 21/266; H01L 29/66

(52) U.S. Cl. CPC H10D 84/154; H01L 21/26513; H01L 21/266; H10D 30/0281; H10D 30/657

(57) ABSTRACT

A semiconductor device includes a first node having a first conductivity type in a semiconductor layer, a second node having a first region with a second, opposite, conductivity type in the semiconductor layer, and a second region adjacent to the first region in the semiconductor layer, and a minority carrier collector having the first conductivity type in the second region of the second node in the semiconductor layer. Another semiconductor device includes an anode in a semiconductor layer, a cathode spaced apart from the anode in the semiconductor layer, and a minority carrier collector adjacent the cathode in the semiconductor layer and having P-type dopants.

### BACKGROUND

Diodes and transistors are used in high voltage applications that require high breakdown voltage ratings and efficient operation, as well as in high speed communications circuitry. Ideal diodes conduct current in the forward bias direction and block all current in the reverse direction with instantaneous response to transition between forward and reverse operation. However, the reversal of a p-n junction from the forward bias condition to a reverse bias condition does not instantaneously stop the current flow. Diode reverse recovery can be detrimental to circuit performance. For example, long reverse recovery times in blocking diodes of high-speed ultrasound transceiver circuits can lead to unwanted glitches that behave like false receive signals. This can be addressed by increasing the delay between transmit and receive events, but this reduces the communication speed.

### SUMMARY

In one aspect, a semiconductor device includes first and second nodes in a semiconductor layer, and a minority carrier collector. The first node has a first conductivity type, and the second node has a first region with a second, opposite, conductivity. The second region is adjacent to the first region in the semiconductor layer, and the minority carrier collector has the first conductivity type in the second region of the second node in the semiconductor layer.

In another aspect, a semiconductor device includes an anode in a semiconductor layer, a cathode spaced apart from the anode in the semiconductor layer, and a minority carrier collector adjacent the cathode in the semiconductor layer and having P-type dopants.

In a further aspect, a method includes implanting dopants of a first conductivity type in a first area in a semiconductor layer, implanting dopants of a second, opposite, conductivity type in a first region of a second area in the semiconductor layer, and implanting dopants of the first conductivity type to form a minority carrier collector in an adjacent second region of the second area in the semiconductor layer.

### BRIEF DESCRIPTION OF THE DRAWINGS

FIG. 1 is a partial sectional side elevation view of an example semiconductor device including a diode with a minority carrier collector adjacent to a cathode taken along line 1-1 in FIG. 1A.

FIG. 1A is a partial sectional top plan view of the semiconductor device taken along line 1A-1A in FIG. 1.

FIG. 1B is a graph with electric field curves near the cathode for a baseline diode without a minority carrier collector and for the diode in FIGS. 1 and 1A with a minority carrier collector adjacent to the cathode.

FIG. 1C is a graph with cathode current and voltage curves for the baseline diode and for the diode in FIGS. 1 and 1A.

FIG. 2 is a partial sectional side elevation view of another example semiconductor device including a diode with alternating minority carrier collector and cathode implants taken along line 2-2 in FIG. 2A.

FIG. 2A is a partial sectional top plan view of the semiconductor device taken along line 2A-2A in FIGS. 2, 2B and 2C.

FIG. 2B is a partial sectional side elevation view of the semiconductor device taken along line 2B-2B in FIG. 2A.

FIG. 2C is a partial sectional side elevation view of another implementation of the semiconductor device with anode minority carrier collectors taken along line 2C-2C in FIG. 2A.

FIG. 3 is a partial sectional side elevation view of another example semiconductor device including a diode with minority carrier collectors adjacent anode areas taken along line 3-3 in FIG. 3A.

FIG. 3A is a partial sectional top plan view of the semiconductor device taken along line 3A-3A in FIG. 3.

FIG. 4 is a flow diagram of a method of fabricating a semiconductor device.

FIGS. 5-8 are partial sectional side elevation views of the semiconductor device of FIGS. 1 and 1A undergoing fabrication processing according to the method of FIG. 4.

FIG. 9 is a partial sectional side elevation view of another example semiconductor device including a drain extended transistor with a minority carrier collector adjacent to a drain.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufactured electronic apparatus such as an integrated circuit or other semiconductor device. While such examples may be expected to provide various improvements, no particular result is a requirement of the present disclosure unless explicitly recited in a particular claim.

Semiconductor devices and fabrication methods are illustrated and described below to facilitate improved reverse recovery in diodes and transistors for enhanced circuit performance without sacrificing breakdown voltage and switching speed. Reduced reverse recovery time allows reduced delay times between transmit and receive events for high speed communications applications. Reverse recovery of a diode or a p-n junction of a transistor structure is a time-dependent behavior. A diode in forward biased conduction will remain in conduction for some time after application of a reverse bias voltage until the carriers responsible for conduction are removed and the charge associated with the junction capacitance is established. The time required for conduction to settle into the reverse bias state is the reverse recovery time, and is dependent on a variety of factors, such as forward current and voltage, diode construction, carrier recombination time, junction capacitance, temperature, etc. Long reverse recovery times are associated with high electric fields and high voltage drop near the cathode. Conventional high-voltage diode structures have n-type dopants in the cathode, but minority carriers (holes) will not be collected efficiently during reverse recovery, making the recovery time long.

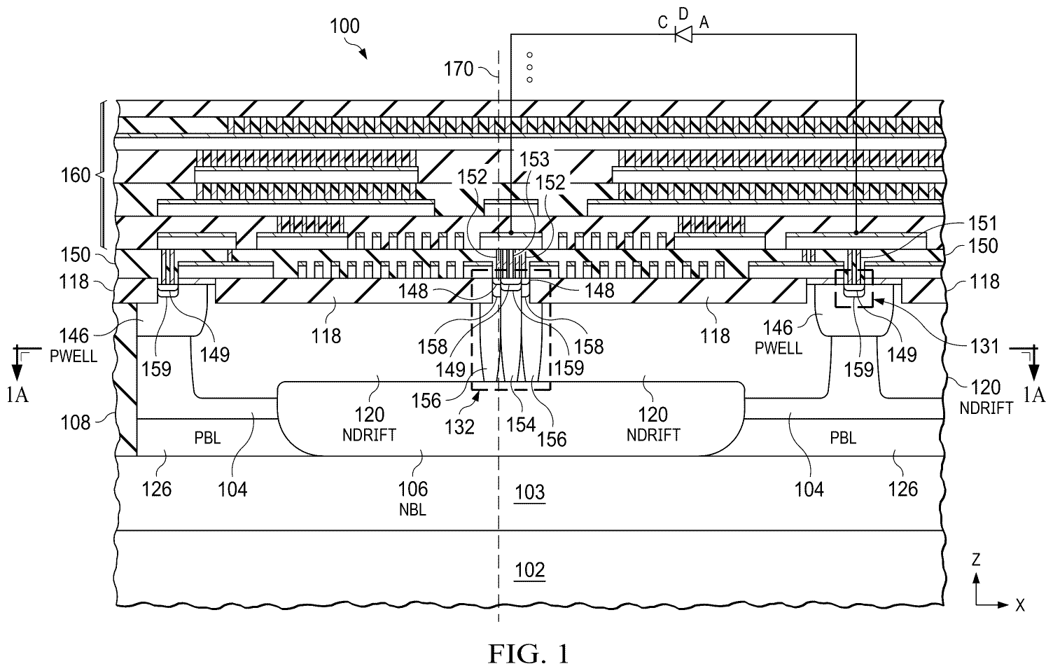

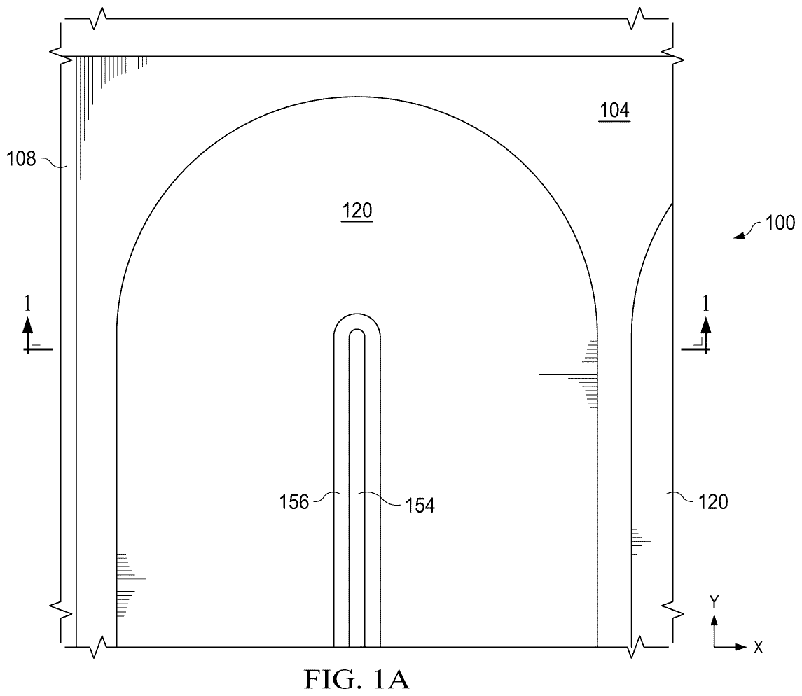

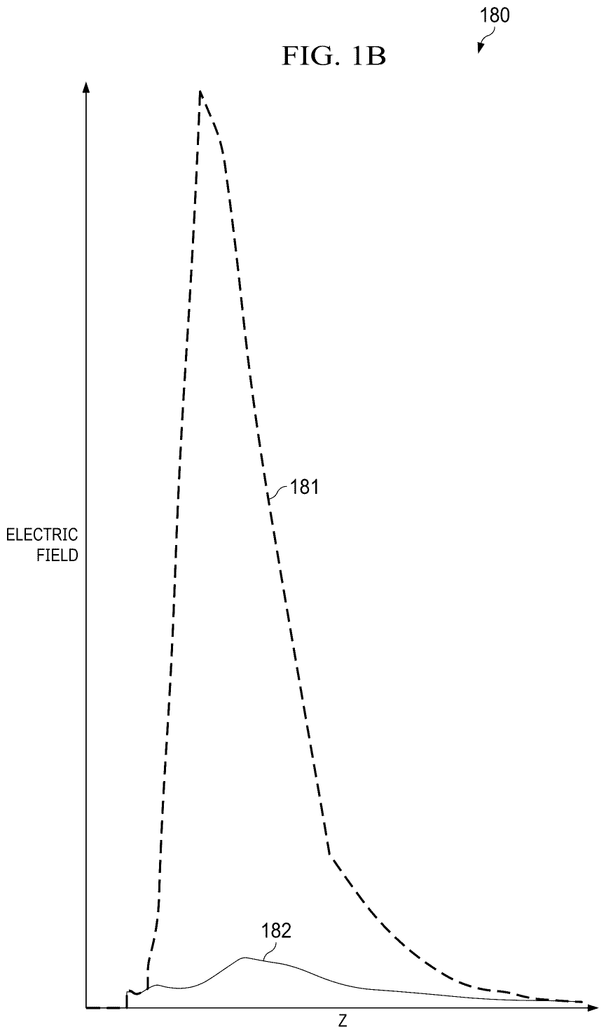

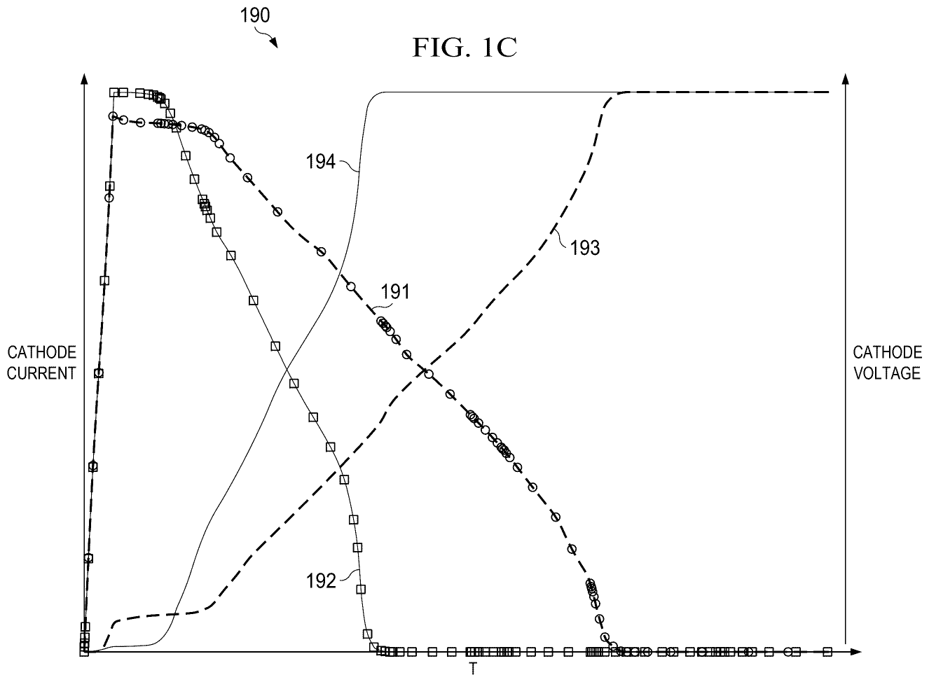

FIGS. 1 and 1A show an example semiconductor device 100 with a diode D schematically illustrated in FIG. 1 with an anode A and a cathode C, including a sacrificial minority carrier collector configured to speed up the diode reverse recovery and facilitate improved performance and reliability. The semiconductor device 100 and other device examples are illustrated in example three-dimensional spaces with a first direction X (e.g., FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. The example device 100 includes a semiconductor substrate 102 (FIG. 1), such as including silicon or other semiconductor material from a starting wafer doped with impurities of a first conductivity type (e.g., P-type), such as a silicon (Si) or other semiconductor wafer (e.g., silicon carbide or SiC, gallium nitride or GaN, etc.), a silicon over insulator (SOI) wafer, etc. An optional buried oxide layer 103 extends on a top side of the semiconductor substrate 102. In another example, the buried oxide layer 103 can be omitted.

A semiconductor layer 104 (e.g., p-type epitaxial silicon) extends over the semiconductor substrate 102 on the buried oxide layer 103 and includes a body region 104 having the first conductivity type (e.g., P-type). A buried layer 106 extends in a portion of the semiconductor layer 104 and has an opposite second conductivity type (e.g., N-type, labeled “NBL” in FIG. 1). A deep trench isolation structure 108 extends along a side of the diode D and into the top side of the semiconductor layer 104, and the deep trench isolation structure 108 in one example can laterally encircle the diode D, although not a requirement of all possible implementations.

The example semiconductor device 100 provides the diode D and includes various implanted regions and structures to accommodate fabrication of transistors that can be concurrently formed in other areas of the semiconductor device 100, although not a requirement of all possible implementations. The device 100 includes a field relief dielectric layer 118, such as a local oxidation of silicon (LOCOS) layer of silicon dioxide (SiO₂). An implanted drift region 120 (e.g., labelled “N-DRIFT” in FIG. 1) has the second conductivity type and extends in the body region 104. The field relief dielectric layer 118 extends over the drift region 120.

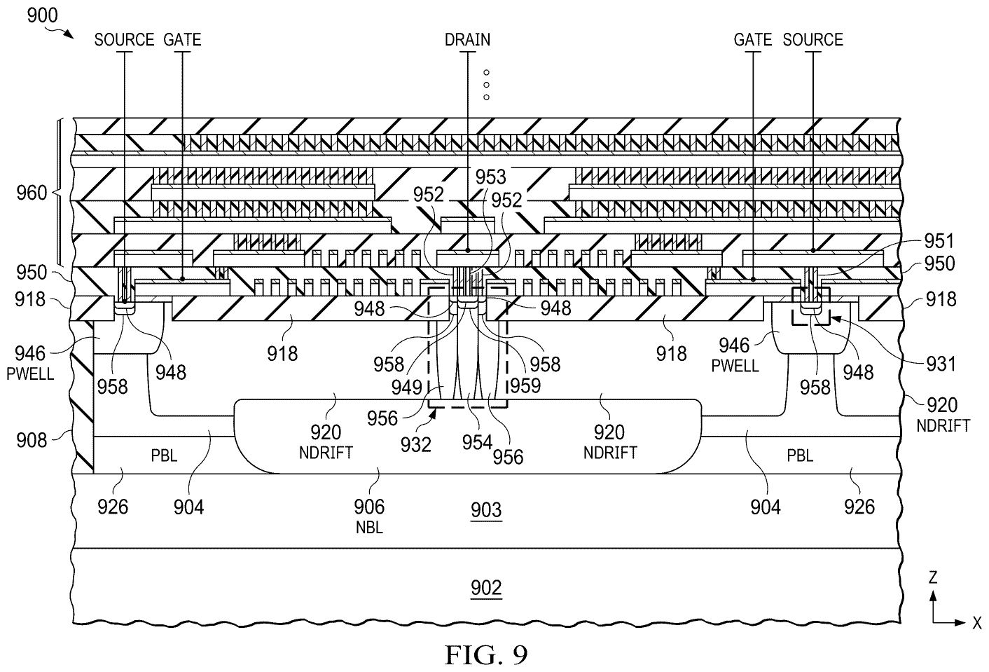

As shown in FIG. 1A, the transistor has a finger or racetrack shape with a center cathode finger and the anode A encircles the cathode. In this or other examples, the diode D can include further cathode-centered finger or racetrack structures (not shown). In these or other implementations, the diode D can include one or more anode-centered finger or racetrack structures and/or one or more cathode-centered finger or racetrack structures (not shown). In these or other implementations, further isolated or non-isolated sections of the semiconductor device 100 can include transistors (e.g., FIG. 9 below) that have single or multiple parallel finger structures (not shown).

As further shown in FIG. 1, the example device 100 can also include a buried layer 126 (e.g., labelled “PBL”, also referred to as a pRESURF layer for safe operating area (SOA) improvement of transistors formed in the semiconductor device 100). The buried layer 126 has the first conductivity type (e.g., P-type) and a dopant concentration greater than the body region 104. The diode D in one example includes a gate dielectric layer near the anodes that extends over a portion of the body region 104 (FIG. 1) and over a junction between the body region 104 and the drift region 120. The gate dielectric layer extends to outer portions of the field relief dielectric layer 118 and over the interface or junction between the p-type body region 104 and the n-type drift region 120 underneath a portion of dummy polysilicon gate structures to facilitate concurrent fabrication with transistors of the semiconductor device 100.

As shown in FIG. 1, the diode D includes a first node 131, also referred to as a first area or region of the semiconductor layer 104 that forms the anode A, as well as a second node 132, also referred to as a second area or region of the semiconductor layer 104 that forms the cathode C and is spaced apart from the first node 131 (e.g., the anode A) in the semiconductor layer 104. The first node 131 has the first conductivity type (e.g., P-type) and the second node 132 has the second conductivity type (e.g., N-type). The cathode-centered finger structure of the diode has a first node 131 that laterally surrounds and is spaced apart from the second node 132 in the section view of FIG. 1 that shows the first node 131 on the right side of the view (the boxed portion) and another portion of the first node 131 along the left side of the view. The semiconductor device 100 includes a deep well region 146 having the first conductivity type (e.g., labelled “PWELL” in FIG. 1) that includes a source/drain implanted region 159 having the first conductivity type (e.g., P-type) with a dopant concentration greater than that of the deep well region 146, as well as a more heavily doped source/drain contact implanted region 149 having the first conductivity type (e.g., P+) along the top side of the semiconductor layer 104. The regions 149 and 159 in at least a portion of the deep well 146 form the first node 131 in one example. The first node 131 in one example is connected by metal contacts 151 through a pre-metal dielectric (PMD) layer 150 to an anode connection through a metallization structure 160. The anode A extends downward through implanted portions of the first conductivity type (e.g., P-type) in the body region of the semiconductor layer 104 to the buried layer 126 that has the first conductivity type (e.g., P-type), and a similar structure is shown on the right and left sides of the section view in FIG. 1.

The diode D includes a p-n junction at the interface of the buried layer 126 that has the first conductivity type (e.g., P-type) and the oppositely doped buried layer 106 (e.g., N-type). In this example, the first conductivity type is P-type, and the second conductivity type is N-type. The cathode-centered structure of the example semiconductor device 100 in FIGS. 1 and 1A has a cathode C (e.g., the second node 132) that includes a first region 156 with the second conductivity type (e.g., N-type) in the semiconductor layer 104. In one example, the first region 156 is a deep N-type well that extends from the buried layer 106 along the third direction Z to the top side of the semiconductor layer 104. In other implementations, the first region 156 may not extend down all the way to the N-type buried layer 106. The first region 156 includes a source/drain implanted region 158 having the second conductivity type (e.g., N-type) with a dopant concentration greater than that of the lower portions of the first region 156, along with a more heavily doped source/drain contact implanted region 148 having the second conductivity type (e.g., N+) along the top side of the semiconductor layer 104. The first region 156 of the second node 132 in one example is connected by metal contacts 152 to a cathode connection through the metallization structure 160.

The second node 132 also includes a second region 154 that is adjacent to the first region 156 in the semiconductor layer 104 and provides a minority carrier collector having the first conductivity type (e.g., P-type) in the second region 154 of the second node 132 in the semiconductor layer 104. As shown in FIG. 1, the second region 154 extends from the top side of the semiconductor layer 104 to the buried layer 106 adjacent to the oppositely doped first region 156. The second region 154 includes another instance of the source/drain implanted region 159 with the first conductivity type (e.g., P-type) with a dopant concentration greater than that of the lower portion of the second region 154, as well as a more heavily doped instance of the source/drain contact implanted region 149 having the first conductivity type (e.g., P+) along the top side of the semiconductor layer 104. The second region 154 of the second node 132 in one example is connected by metal contacts 153 through the PMD dielectric 150 to the cathode connection through the metallization structure 160. In another example, the contacts 153 to the second region 154 of the second node 132 can be omitted. In various implementations, a continuous silicide structure (not shown) can be used to connect the first and second regions 156 and 154 to facilitate minority carrier collection in reverse recovery operation through shared or separate contacts to the metallization structure 160.

As further shown in FIG. 1A, the first and second regions 156 and 154 of the second node 132 extend along a finger direction (e.g., second direction Y) in the semiconductor layer 104. In one implementation, the first and second regions 156 and 154 are approximately parallel to one another and at least partially adjacent to one another. For example, the first region 156 of the second node 132 can be a stripe that extends along the finger direction Y, and the second region 154 of the second node 132 extends along the finger direction Y adjacent to the first region 156. The positioning and opposite doping of the second region 154 of the second node 132 provides minority carrier collection to facilitate fast reverse recovery of the diode D. In the illustrated example, the second region 154 is a stripe that extends along the finger direction Y, and the first region 156 of the second node 132 encircles the second region 154 of the second node 132. As shown in FIG. 1A. In this manner, the cathode C is adjacent to and laterally encircles the oppositely doped minority carrier collector of the second portion 154. In one example, the dopant concentration of the minority carrier collector in the P-type second region 154 of the second node 132 is less than the dopant concentration of the N-type first region 156 of the second node 132, although not a requirement of all possible implementations.

Referring also to FIGS. 1B and 1C, FIG. 1B shows a graph 180 with electric field curves 181 and 182 as a function of vertical distance along the third direction Z during reverse recovery near the cathode of a baseline diode (curve 181) without a minority carrier collector, and near the cathode of the diode D in FIGS. 1 and 1A (curve 182) with the minority carrier collector provided by the second region 154 adjacent to the cathode of the first region 156 of the second node 132—e.g., along the line 170 in FIG. 1 through the heavily doped source/drain contact implanted region 148, the source/drain implanted region 158, and the deep N-type well of the first region 156. As shown in FIG. 1B, the lack of a minority carrier collector in the baseline diode leads to high electric field near the cathode (curve 181). In contrast, the inclusion of the P-type second region 154 of the second node 132 collects holes (minority carriers) from the first region 156 of the second node 132, resulting in significantly lower electric fields (curve 182) near the cathode.

FIG. 1C shows a graph 190 with cathode current and voltage curves as a function of time “t” during diode reverse recovery for the baseline diode without a minority carrier collector and for the diode D in FIGS. 1 and 1A. The graph 190 includes a first current curve 191 showing the cathode current of the baseline diode (with no minority carrier collector) during reverse recovery, as well as a second current curve 192 showing the cathode current of the diode D in FIGS. 1 and 1A during reverse recovery. The curve 192 shows the significant reduction in the current reversal time (reverse recovery) of the diode D having the minority carrier (e.g., hole) collector provided by the P-type second region 154 of the second node 132 that collects minority holes from the cathode of the first region 156. In particular, the cathode current shown in curve 192 discharges much quicker than the current (curve 191) of the baseline diode, without significant change in the peak forward current. The improved diode D facilitates minority carrier collection during reverse recovery to significantly reduce the reverse recovery time.

In addition, the graph 190 in FIG. 1C includes a first cathode voltage curve 193 that shows the cathode voltage of the baseline diode, as well as a second cathode voltage curve 194 that shows the cathode voltage of the example diode D with a minority carrier collector at the cathode in FIGS. 1 and 1A during reverse recovery. The cathode voltage (curve 194) of the device with the minority carrier collector rises to the peak voltage much faster than the baseline diode device (curve 193). In operation, incorporating a minority carrier collector adjacent the oppositely doped cathode of the diode D provides significant reduction in the reverse recovery charge (e.g., Qrr reduction) for hole collectors without affecting breakdown voltage of the device 100, and without adversely impacting circuit operation, particularly for fast switching times in communications circuits. In addition to reducing Qrr, the stripe-shaped cathode and minority carrier collector structures (e.g., FIG. 1A) provide high diode reliability with high safe operating area (SOA) which is helped in part by the absence of a high electric field near the cathode (e.g., the low electric field shown in curve 182 of FIG. 1B).

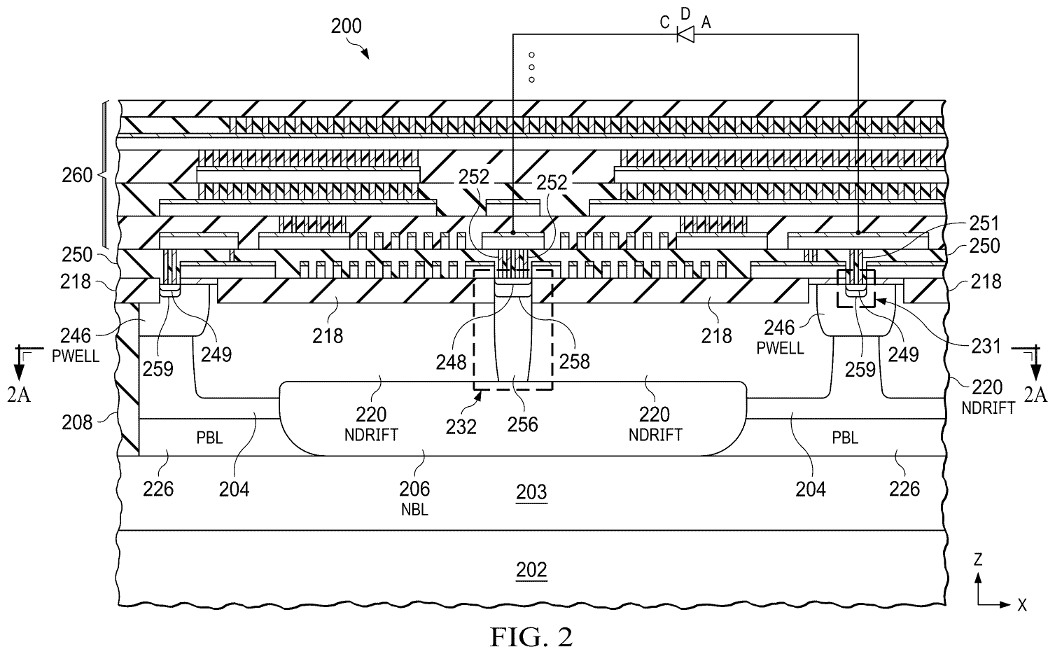

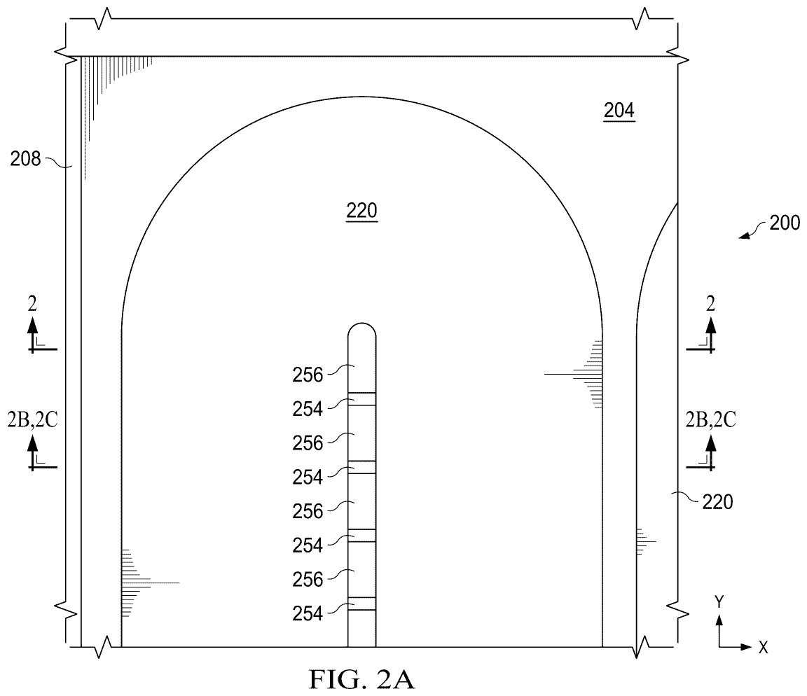

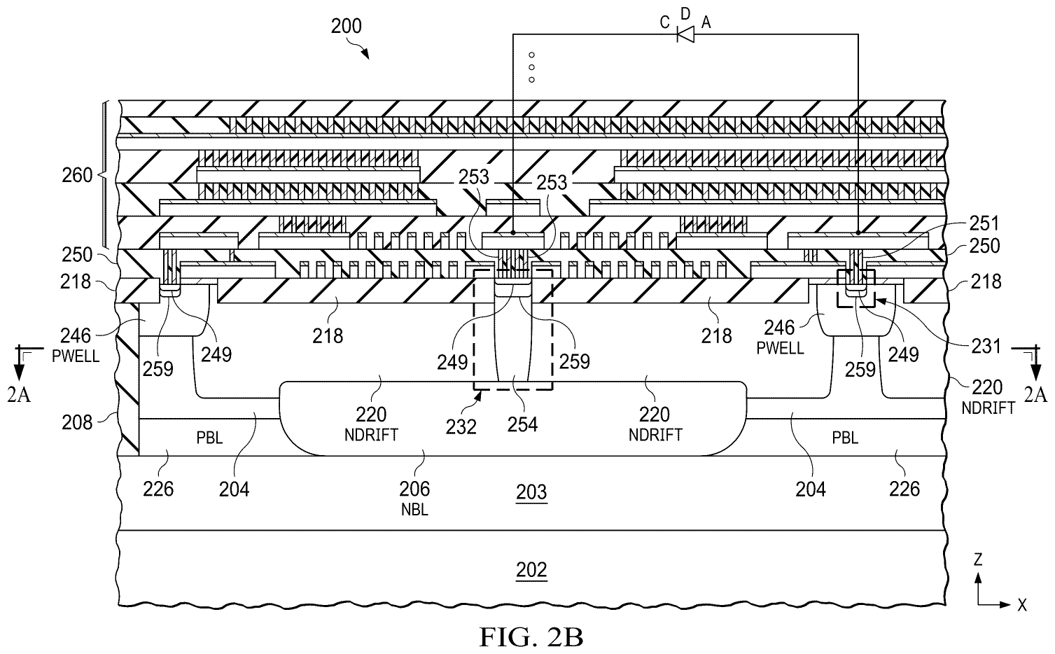

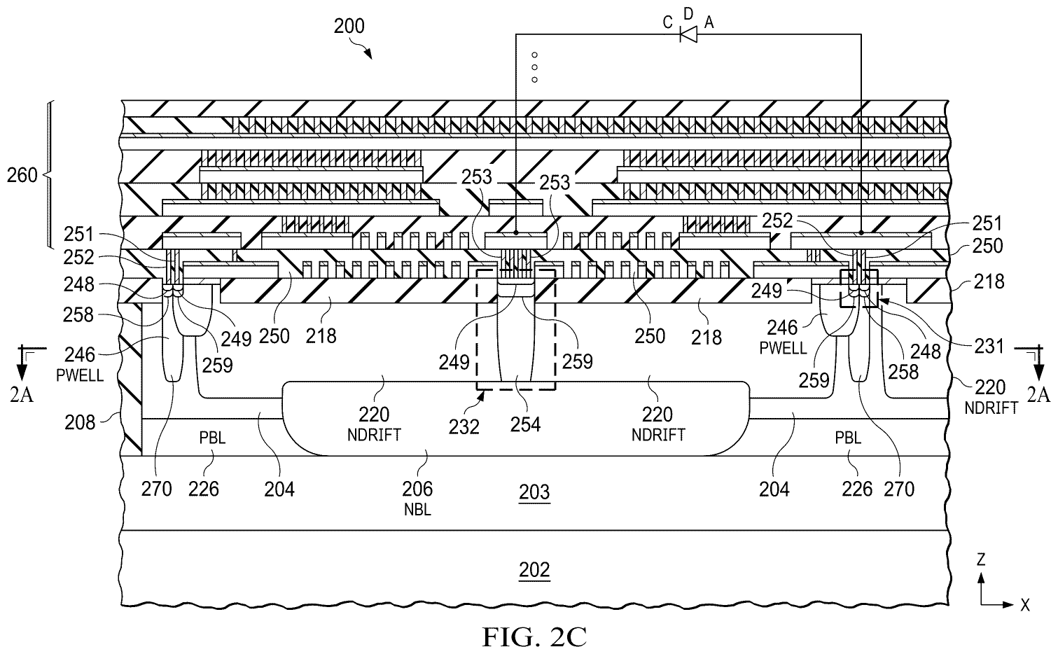

Referring also to FIGS. 2-2C, further examples provide cathode and/or anode-based minority carrier collector structures to facilitate fast reverse recovery performance. FIGS. 2-2B illustrate another example semiconductor device 200 including a diode D with a cathode C and an anode A. In one example, the electronic device 200 has one or more structures and features 202-204, 206, 208, 218, 220, 226, 231, 232, 246, 248-254, 256, 258, and 260 that can be the same or similar to the respective structures and features 102-104, 106, 108, 118, 120, 126, 131, 132, 146, 148-154, 156, 158, and 160 illustrated and described above in connection with the electronic device 100 of FIGS. 1 and 1A, except as noted hereinafter.

The semiconductor device 200 has a cathode C with alternating minority carrier collector and cathode implants along a finger direction (e.g., the second direction Y as shown in FIG. 2A. FIG. 2 shows a partial sectional side view along line 2-2 in FIG. 2A through an instance of a first region 256 of the second node 232 with the second conductivity type (e.g., N-type) in the semiconductor layer 204 that extends from the buried layer 206 along the third direction Z to the top side of the semiconductor layer 204. The first region 256 includes a source/drain implanted region 258 having the second conductivity type (e.g., N-type) with a dopant concentration greater than that of the lower portions of the first region 256, along with a more heavily doped source/drain contact implanted region 248 having the second conductivity type (e.g., N+) along the top side of the semiconductor layer 204. The first region 256 of the second node 232 shown in FIG. 2 of is connected by metal contacts 252 to a cathode connection through the metallization structure 260.

As shown in FIGS. 2 and 2B, the diode D includes the first node 231 that forms the anode A having the first conductivity type (e.g., P-type) and the first node 231 of the cathode-centered finger structure laterally surrounds and is spaced apart from the second node 232 in the section views of FIGS. 2 and 2B. These figures show the first node 231 on the right side of the view (the boxed portion) and another portion of the first node 231 along the left side. The semiconductor device 200 includes a deep well region 246 having the first conductivity type (e.g., labelled “PWELL” in FIG. 2) that includes a source/drain implanted region 259 having the first conductivity type (e.g., P-type) with a dopant concentration greater than that of the deep well region 246, as well as a more heavily doped source/drain contact implanted region 249 having the first conductivity type (e.g., P+) along the top side of the semiconductor layer 204.

The regions 249, 259 in at least a portion of the deep well 246 form the first node 231 in one example. The first node 231 in one example is connected by metal contacts 251 through a pre-metal dielectric (PMD) layer 250 to an anode connection through a metallization structure 260. The anode A extends downward through implanted portions of the first conductivity type (e.g., P-type) in the body region of the semiconductor layer 204 to the buried layer 226 that has the first conductivity type (e.g., P-type). The right and left sides of the section views of FIGS. 2 and 2B show similar portions of the encircling anode structure.

FIG. 2B shows a partial sectional side view along line 2B-2B in FIG. 2A through an instance of the second region 254 of the second node 232. The individual instances of the second region 254 are adjacent to at least one instance of the first region 256 in the semiconductor layer 204 and provide a minority carrier collector instance having the first conductivity type (e.g., P-type). As shown in FIG. 2B, the second region 254 extends from the top side of the semiconductor layer 204 to the buried layer 206 adjacent to the oppositely doped first region 256 of FIG. 2, although not a requirement of all possible implementations. In another example, a shallower second region 254 can be used, which may not extend all the way down to the buried layer 206. The second region instance 254 includes another instance of the source/drain implanted region 259 with the first conductivity type (e.g., P-type) with a dopant concentration greater than that of the lower portion of the second region 254, as well as a more heavily doped instance of the source/drain contact implanted region 249 having the first conductivity type (e.g., P+) along the top side of the semiconductor layer 204. The second region instances 254 of the second node 232 in one example are connected by metal contacts 253 (FIG. 2B) through the PMD dielectric 250 to the cathode connection through the metallization structure 260. In another example, the contacts 253 to the second region instances 254 of the second node 232 can be omitted. The alternating adjacent p-type second regions 254 of the cathode collect the minority carriers (holes) stored in the region during reverse recovery to help speed up the reverse recovery time.

FIG. 2C shows a partial sectional side view of another implementation of the semiconductor device 200 with additional anode minority carrier collectors taken along line 2C-2C in FIG. 2A. In this implementation, reverse recovery can be further helped by a second minority carrier collector 270 having the second conductivity type (e.g., N-type) adjacent to the first node 231 (e.g., adjacent to the encircling anode structure) in the semiconductor layer 204. In some implementations, the minority carrier collector region 270 may be a shallow region, for example, shallower than the deep well region (PWELL 246), although for illustration purposes it is shown to be deeper in the example of FIG. 2C. The second minority carrier collector 270 includes N-type implanted regions (e.g., heavily doped source/drain contact implanted region 248 and source/drain implanted region 258) and is connected to the anode A of the diode D by contacts 252. In the illustrated implementation, the second minority carrier collector 270 (e.g., N-type source/drain implant and/or N-type well implant) is added to the anode side to collect electrons (minority carriers in the anode region) during diode reverse recovery. The example of FIG. 2C combines the added N-type minority carrier collector 270 in combination with the P-type minority hole collectors on the cathode side (e.g., alternating second regions 254 described above). These structures 270 can be engineered (e.g., avoiding a parasitic p-n-p-n thyristor latch up) to provide further improvement in reducing reverse recovery charge Qrr. In one example, the N-type minority carrier collector 270 can be a continuous encircling structure spaced apart from and laterally surrounding the finger structure of the cathode center. In another example, segments of N-type minority carrier collectors 270 can be used. The minority carrier collector structures can be connected to the metallization structure 260 by suitable contacts and/or silicide connections to facilitate minority carrier collection during diode reverse recovery.

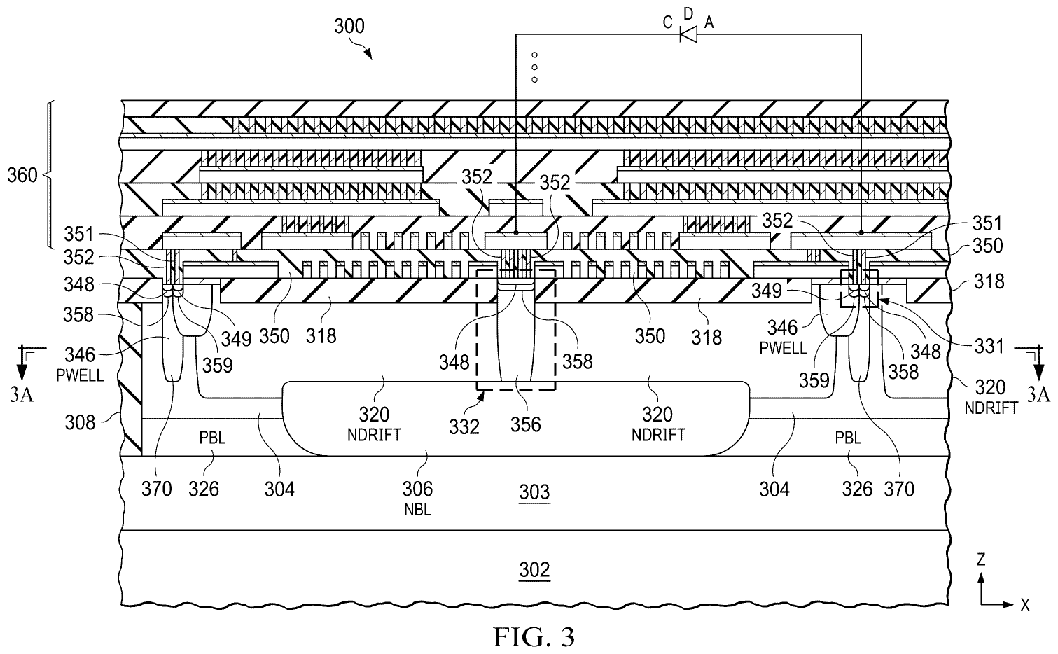

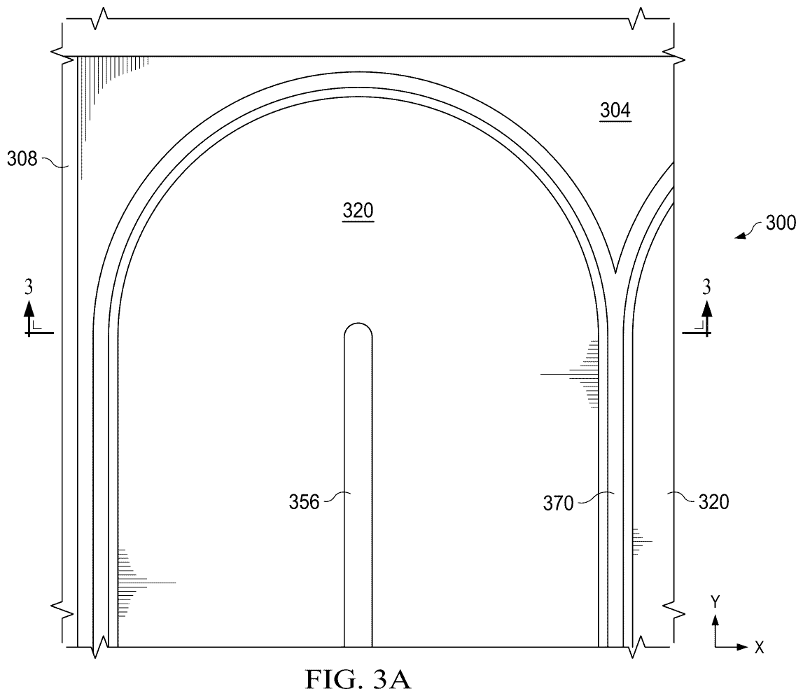

FIGS. 3 and 3A show another example semiconductor device 300 which incorporates the anode-side N-type minority carrier (electron) collector approach alone (e.g., without the cathode-side P-type minority carrier (hole) collectors). FIG. 3 shows a partial sectional side view of the semiconductor device 300 taken along line 3-3 in the partial sectional top view of FIG. 3A. In one example, the electronic device 300 has one or more structures and features 302-304, 306, 308, 318, 320, 326, 331, 332, 346, 348-352, 356, 358, and 360 that can be the same or similar to the respective structures and features 102-104, 106, 108, 118, 120, 126, 131, 132, 146, 148-152, 156, 158, and 160 illustrated and described above in connection with the electronic device 100 of FIGS. 1 and 1A, except as noted hereinafter. This example includes a minority carrier collector 370 to help reverse recovery. The minority carrier collector 370 has the second conductivity type (e.g., N-type) adjacent to the first node 331 (e.g., adjacent to the encircling anode structure) in the semiconductor layer 304. In the illustrated implementation, an N-type region 370 (e.g., N-type source/drain implant and/or N-type well implant) is added to the anode side to collect minority carriers (electrons) during diode reverse recovery. The example minority carrier collector structure 370 can be engineered (e.g., avoiding a parasitic p-n-p-n thyristor latch up) to help reduce reverse recovery charge Qrr. In one example, the N-type minority carrier collector 370 can be a continuous encircling structure spaced apart from and laterally surrounding the cathode-center finger structure. In another example, segments of N-type minority carrier collectors 370 can be used. The minority carrier collector 370 can be connected to the metallization structure 360 by any suitable contacts through the PMD layer 350 along or in combination with silicide connections to facilitate minority carrier collection to aid reverse recovery.

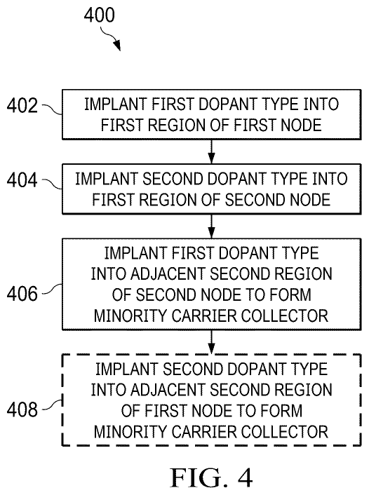

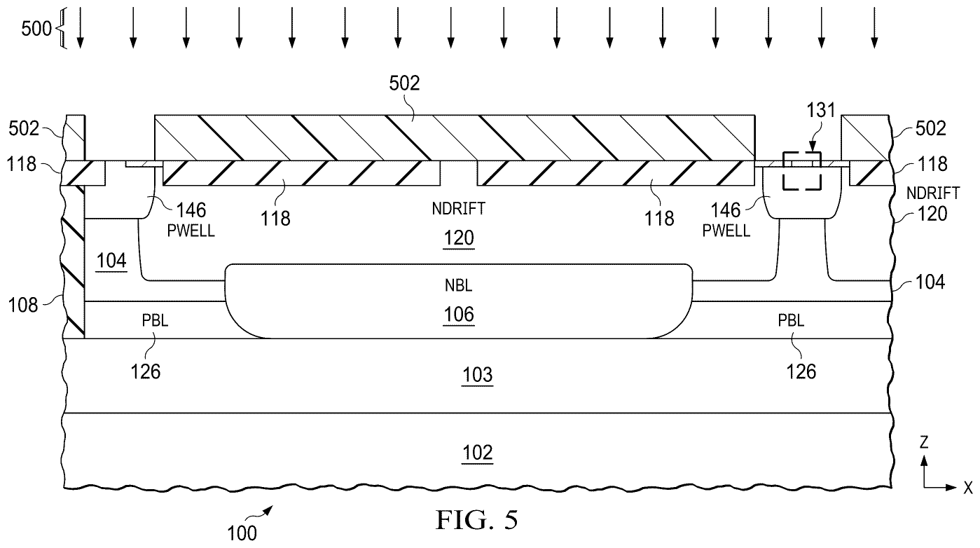

Referring also to FIGS. 4-8, FIG. 4 shows a method 400 of fabricating a semiconductor device and FIGS. 5-8 illustrate an example semiconductor device including aspects of the semiconductor devices 100, 200, 300 described with reference to FIGS. 1 through 3A, undergoing fabrication processing according to the method 400. In the following description, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), plasma enhanced CVD (PECVD), or atomic layer deposition (ALD), for example. In addition, terms such as top, bottom, and under may be used in this disclosure, and such terms should not be construed as limiting the position or orientation of a structure or element but should be used to provide spatial relationship between structures or elements. Described examples include doped regions of various semiconductor structures which may be characterized as p-doped (e.g., P-type) and/or n-doped (e.g., N-type) areas, regions or portions and include regions that have majority carrier dopants of a particular type, such as n-type dopants or p-type dopants.

The various implantations of the example method can be done in different orders and some implantations may be performed concurrently in various implementations. The method 400 in FIG. 4 in one example includes implanting dopants of a first conductivity type (e.g., P-type) at 402 in a first area in a semiconductor layer. FIG. 5 shows one example, in which an implantation process 500 is performed that implants P-type dopants (e.g., boron) into a first area (corresponding to the first node 131) of the semiconductor layer 104 to form the deep well 146. The implantation process 500 uses a mask 502 with openings corresponding to the first area along the top side of the semiconductor layer 104. In one example, the implantation process 500 can be used to concurrently implant other P-type regions or areas of the semiconductor layer 104, for example, source/drain implants for a concurrently formed transistor (not shown).

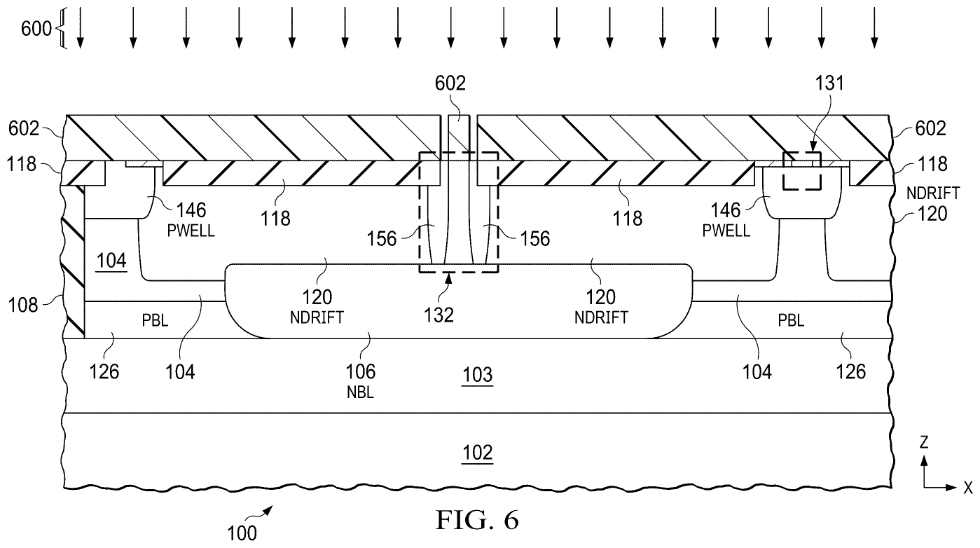

The method 400 continues at 404 in FIG. 4 with implanting dopants of an opposite second conductivity type (e.g., N-type) into a second area of the semiconductor layer. FIG. 6 shows one example, in which an implantation process 600 is performed with an implant mask 602 in order to implant N-type dopants (e.g., phosphorus) into a second area (corresponding to the second node 132) to form the first region 156 as described above. In one example, the implantation process 600 can be used to concurrently implant other N-type regions or areas of the semiconductor layer 104, for example, source/drain implants for a concurrently formed transistor (not shown).

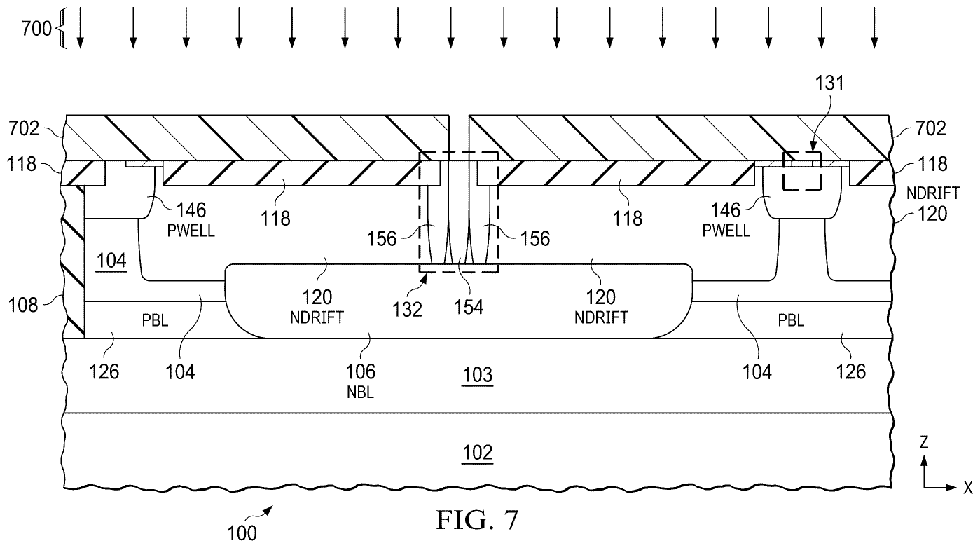

At 406 in FIG. 4, the method 400 includes implanting dopants of the first conductivity type (e.g., P-type) to form a minority carrier collector in an adjacent second region 154 (e.g., adjacent to the first region 156) of the second area in the semiconductor layer 104. FIG. 7 shows one example, in which an implantation process 700 is performed that implants boron or other P-type dopants into the second region 154 of the second area corresponding to the second node 132 in the semiconductor layer 104. This creates an adjacent minority carrier collector structure 154 adjacent to the prospective cathode of the ultimately formed diode as described above in connection with FIGS. 1 and 1A. In one example, the dopant concentration of the minority carrier collector of the second region 154 is less than the dopant concentration of the first region 156 of the second area corresponding to the second node 132, although not a requirement of all possible implementations.

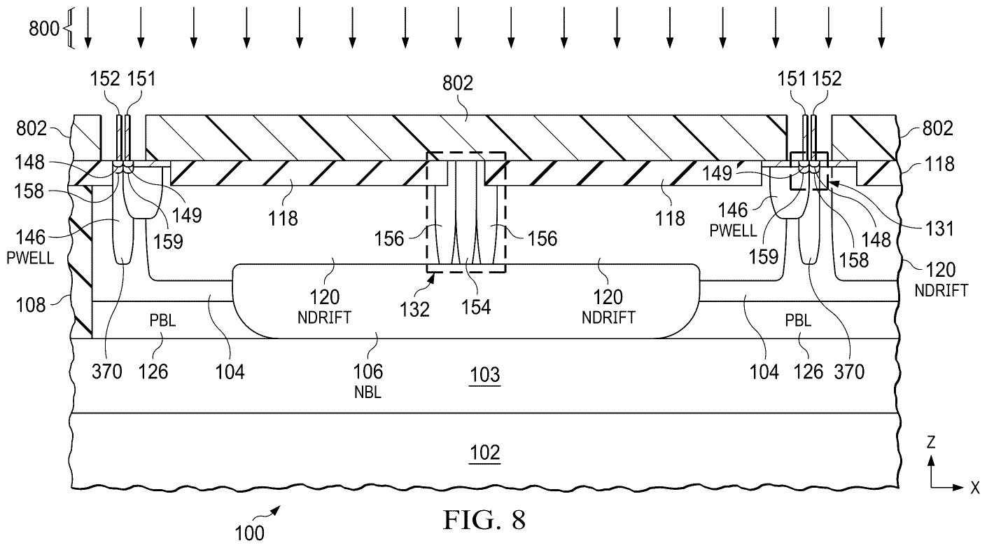

In one example, the method 400 continues at 408 in FIG. 4 with implanting the second dopant type (e.g., dopants of the second conductivity type) into an adjacent second region of the first node to form an additional minority carrier collector. FIG. 8 shows one example, in which an implantation process 800 is performed with an implant mask 802 in order to implant N-type dopants (e.g., phosphorus) to form the anode-side minority carrier collectors 370, for example, as described above in connection with FIGS. 3 and 3A. In the illustrated example, the anode-side N-type minority carrier collectors (e.g., electron collectors) 370 can be formed in combination with the cathode-side P-type minority carrier collector 154, although not a requirement of all possible implementations. In another implementation, the additional implant at 408 in FIG. 4 can be omitted. The illustrated examples can be implemented in semiconductor fabrication processes with little or no added cost or processing time. For example, the implantation of the second region 154 of the minority carrier collector structure (e.g., the process 700 and FIG. 7) can be concurrently used for implanting other P-type regions of a processed wafer, and the adaptation of the process 700 to implant the second region 154 of the second node 132 can be a simple change to the implant mask 702 without adding any additional cost or complexity to the manufacturer of an integrated circuit or other semiconductor device.

FIG. 9 shows a partial sectional side view of another example semiconductor device 900 that includes a drain extended transistor. The transistor in FIG. 9 can be formed in a semiconductor device (e.g., devices 100, 200, 300 above) that also includes a diode having added minority carrier collector structures as described above. In another example, the semiconductor device 900 of FIG. 9 need not include any diodes. The illustrated example has a minority carrier collector adjacent to a drain of the transistor, and the transistor is formed in a racetrack or finger structure arrangement with a drain at the center of the finger structure and gate and source features that laterally encircle the center drain. In one example, the electronic device 900 has one or more structures and features 902-904, 906, 908, 918, 920, 926, 931, 932, 946, 948-953, 956, 958, and 960 that can be the same or similar to the respective structures and features 102-104, 106, 108, 118, 120, 126, 131, 132, 146, 148-153, 156, 158, and 160 illustrated and described above in connection with the electronic device 100 of FIGS. 1 and 1A, except as noted hereinafter. The example transistor in FIG. 9 is an n-channel laterally diffused metal oxide semiconductor (NMOS or NMOS LDMOS), where the drift region 920 is a drain drift region. P-channel metal oxide transistors (PMOS) LDMOS transistors can be formed when n-doped regions are substituted by p-doped regions and p-doped regions are substituted by n-doped regions in another implementation. The source and drain terminals in this example include instances of the N-type source/drain implanted region 958 having the second conductivity type (e.g., N-type) along with a more heavily doped source/drain contact implanted region 948 having the second conductivity type (e.g., N+) along the top side of the semiconductor layer 904. In addition, the center drain structure provides the second node 932 that includes N-type first portions 956 as well as P-type second portions 954 that provide a minority carrier collector structure adjacent the first portions 956 to collect minority carriers (hole) to facilitate fast reverse recovery of the transistor.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A semiconductor device, comprising:
a first node having a first conductivity type in a semiconductor layer;
a second node having a first region with a second, opposite, conductivity type in the semiconductor layer, and a second region adjacent to the first region in the semiconductor layer; and
a minority carrier collector having the first conductivity type in the second region of the second node in the semiconductor layer.

2. The semiconductor device of claim 1, wherein the second node extends along a finger direction in the semiconductor layer, the first region of the second node is a stripe that extends along the finger direction, and the second region of the second node extends along the finger direction adjacent to the first region.

3. The semiconductor device of claim 2, wherein the first region of the second node encircles the second region of the second node.

4. The semiconductor device of claim 1, wherein the second node includes alternating adjacent instances of the first and second regions along a finger direction in the semiconductor layer.

5. The semiconductor device of claim 1, comprising a second minority carrier collector having the second conductivity type adjacent to the first node in the semiconductor layer.

6. The semiconductor device of claim 1, wherein the first node is an anode of a diode, and the second node is a cathode of the diode.

7. The semiconductor device of claim 1, wherein the first node is a source of a transistor, and the second node is a drain of the transistor.

8. The semiconductor device of claim 1, wherein the first conductivity type is P-type and the second conductivity type is N-type.

9. The semiconductor device of claim 1, wherein the first conductivity type is N-type and the second conductivity type is P-type.

10. The semiconductor device of claim 1, wherein the minority carrier collector in the second region of the second node is adjacent to the first region of the second node.

11. A semiconductor device, comprising:
an anode in a semiconductor layer;
a cathode spaced apart from the anode in the semiconductor layer; and
a minority carrier collector adjacent the cathode in the semiconductor layer and having P-type dopants.

12. The semiconductor device of claim 11, wherein the cathode extends along a finger direction in the semiconductor layer, and the minority carrier collector extends along the finger direction.

13. The semiconductor device of claim 12, wherein the cathode encircles the minority carrier collector.

14. The semiconductor device of claim 11, comprising alternating adjacent instances of the cathode and the minority carrier collector along a finger direction in the semiconductor layer.

15. The semiconductor device of claim 11, comprising an N-type second minority carrier collector adjacent to the anode in the semiconductor layer.

16. A method, comprising:
implanting dopants of a first conductivity type in a first area in a semiconductor layer;
implanting dopants of a second, opposite, conductivity type in a first region of a second area in the semiconductor layer; and
implanting dopants of the first conductivity type to form a minority carrier collector in an adjacent second region of the second area in the semiconductor layer.

17. The method of claim 16, further comprising implanting dopants of the second conductivity type to form a second minority carrier collector adjacent to the dopants of the first conductivity type of the first area in the semiconductor layer.
